(19) United States
(12) Patent Application Publication
(10) Pub. No.: US 2007/0117280 A1
(43) Pub. Date: May 24, 2007

(54) Manufacturing liquid crystal display substrates

(76) Inventors: Yeong-Beom Lee, Chungcheognam-do (KR); Myung-Il Park, Daejeon (KR); Kyung-Seop Kim, Gyeonggi-do (KR); Yong-Eui Lee, Gyeonggi-do (KR)

Correspondence Address: MACPHERSON KWOK CHEN & HEID LLP, 2033 GATEWAY PLACE, SUITE 400, SAN JOSE, CA, 95110, US

(21) Appl. No.: 11/529,177

(22) Filed: Sep. 27, 2006

(30) Foreign Application Priority Data
Sep. 27, 2005 (KR) 2005-89856

(51) Int. Cl. H01L 21/84

(52) U.S. Cl. 438/149

(57) ABSTRACT

Methods and apparatus for manufacturing an LCD substrate include forming a gate electrode of a pixel switching element on a base substrate, forming a gate insulating layer on the base substrate, forming a source electrode and a drain electrode of the switching element on the gate insulating layer, forming a protective insulating layer on the base substrate, radiating a laser beam onto the substrate so as to form a first contact hole exposing a small portion of the drain electrode, and forming the pixel electrode on the substrate such that it is electrically connected to the drain electrode through the first contact hole. The methods and apparatus both simplify the process of manufacturing an LCD substrate and make it more reliable.

### RELATED APPLICATIONS

This application claims priority of Korean Patent Application No. 2005-89856, filed Sep. 27, 2005, the entire contents of which are incorporated herein by reference.

### BACKGROUND

This invention relates to methods and apparatus for manufacturing liquid crystal display (LCD) substrates, and more particularly, to methods and apparatus that simplify and enhance the reliability of the processes used to manufacture an LCD substrate.

An LCD displays an image by use of the optical characteristics of a liquid crystal material in which the molecules of the material are rearranged when electric fields are applied thereto. An LCD includes a display panel having an array substrate, an opposite substrate and a liquid crystal layer disposed between the array substrate and the opposite substrate. The array substrate includes a plurality of gate lines and a plurality of data lines that intersect but do not connect to the gate lines. The array substrate includes a plurality of pixel portions defined by the gate lines and the data lines. Each of the pixel portions includes a thin-film transistor (TFT) that functions as a switch. The TFT is electrically coupled to the gate lines, the data lines, and a pixel electrode.

Both the array substrate and the opposite substrate are typically manufactured with photolithography processes. The photolithography processes includes a photoresist (PR) coating process, a drying process, an exposing process, a developing process, a heat treatment process and an etching process. As display substrates becomes larger, the photolithography apparatus used for manufacturing the display substrate also becomes correspondingly larger, up to certain practical limits on the size of the apparatus.

Accordingly, there is a long felt but as yet unsatisfied need in the industry for new methods and apparatus for manufacturing large LCD substrates that are simple, inexpensive, and reliable in use.

### BRIEF SUMMARY

In accordance with the exemplary embodiments thereof described herein, the present invention provides methods and apparatus for manufacturing large LCD substrates that are simpler, more efficient, and more reliable than the photolithographic methods and apparatus of the prior art.

In one exemplary embodiment of the present invention, an LCD substrate includes a plurality of pixel portions, each comprising a switching element electrically connected to a gate line and a source line, and a pixel electrode electrically connected to the switching element. An exemplary embodiment of a method for manufacturing the display substrate includes forming a gate electrode of the switching element on a base substrate, forming a gate insulating layer on the base substrate having the gate electrode, forming a source and drain electrode of the switching element on the gate insulating layer, forming a passivation layer on the base substrate having the source and the drain electrode formed thereon, radiating a laser beam onto the passivation layer to form a first contact hole that exposes a portion of the drain electrode, and forming the pixel electrode electrically connected to the drain electrode through the first contact hole.

An exemplary embodiment of an apparatus for manufacturing the display substrate in accordance with the present invention includes a head section, a head transferring section and a stage section. The head section emits a laser beam. The transferring section fixes the head section and moves it to selected positions. A display substrate including the insulating layer is disposed on the stage section and the insulating layer is patterned by the laser beam.

The methods and apparatus of the invention enable the process of manufacturing large LCD substrates to be simplified yet more reliable by patterning the insulating layer of the display substrate using the laser beam instead of using the photolithographic techniques of the prior art.

A better understanding of the above and many other features and advantages of the manufacturing methods and apparatus of the present invention and their advantageous application to the manufacture of LCD substrates may be obtained from a consideration of the detailed description of some exemplary embodiments thereof below, particularly if such consideration is made in conjunction with the appended drawings, wherein like reference numerals are used to identify like elements illustrated in one or more of the figures thereof.

### BRIEF DESCRIPTION OF THE DRAWINGS

FIG. 1 is a partial upper side perspective view of an exemplary embodiment of an apparatus for manufacturing an LCD substrate in accordance with the present invention;

FIG. 2 is a partial upper side perspective view of a head section of the apparatus of FIG. 1;

FIGS. 3A to 3C are partial upper side and cross-sectional views of the apparatus of FIG. 1 being used in three exemplary patterning methods of the invention;

FIG. 4 is a partial upper side perspective view of the head section of an exemplary alternative embodiment of an apparatus for manufacturing an LCD substrate in accordance with the present invention;

FIGS. 5A to 5D are sequential partial cross-sectional views of an insulating layer on an LCD substrate being patterned with the alternative apparatus of FIG. 4;

FIG. 6 is a partial plan view of an exemplary LCD substrate manufactured by the apparatus of FIGS. 1 and 4;

FIGS. 7A to 7E are sequential partial cross-sectional views of the LCD substrate of FIG. 6 corresponding to cross-sectional views taken along the section line I-I′ therein, showing the sequential steps of a first exemplary embodiment of a method for manufacturing the substrate in accordance with the present invention;

FIGS. 8A to 8D are sequential partial cross-sectional views of the LCD substrate of FIG. 6 corresponding to cross-sectional views taken along the section line I-I′ therein, showing the sequential steps of a second exemplary embodiment of a method for manufacturing the substrate in accordance with the present invention; and,

FIG. 9 is a partial cross-sectional view of the display substrate 120 taken along the lines II-II′ in FIG. 6 and illustrating the manufacture of the display substrate in accordance with another aspect of the present invention.

### DETAILED DESCRIPTION

It should be understood that the exemplary embodiments of the present invention described below may be varied modified in many different ways without departing from the inventive principles disclosed herein, and the scope of the present invention is therefore not limited to these particular flowing embodiments. Rather, these embodiments are provided so that this disclosure will be thorough and complete, and will fully convey the concept of the invention to those skilled in the art by way of example and not of limitation. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the embodiments of the present invention will be described in detail with reference to the accompanied drawings.

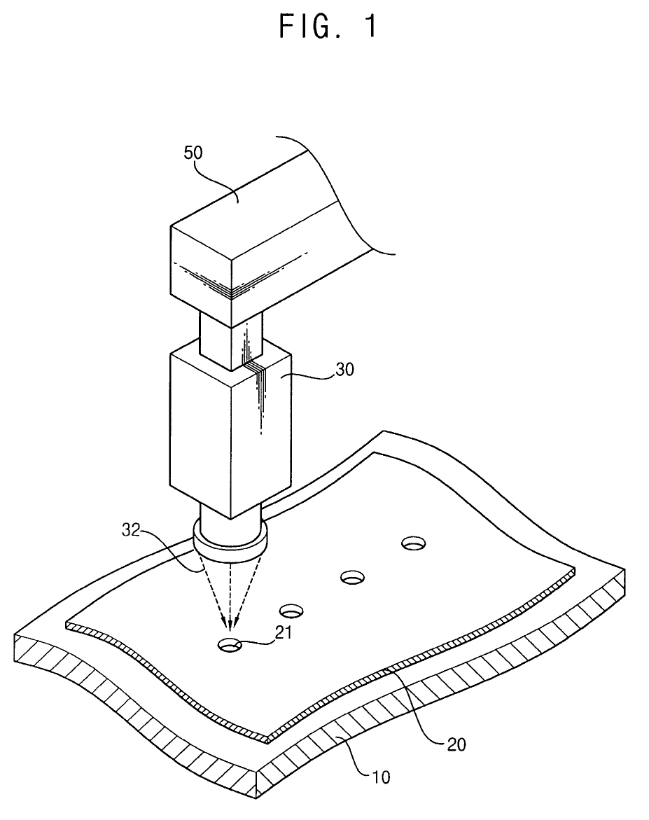

FIG. 1 is a partial upper side perspective view of an exemplary embodiment of an apparatus for manufacturing an LCD substrate in accordance with the present invention. With reference to FIG. 1, the apparatus includes a stage section 10, a head section 30 and a transferring section 50. The head section 30 is disposed above the stage section 10 so that a laser beam radiating from the former can be focused onto an object disposed on the latter. In FIG. 1, an LCD substrate 20 having an insulating layer on it that is to be patterned is disposed on the stage section 10 and supported by it. The head section 30 is arranged to radiate a laser beam 32 onto the substrate 20 so as to burn a desired pattern 21 into the insulating layer formed on the substrate 20 in the manner described below. The insulating layer may comprise a passivation layer or an organic insulating layer. The pattern 21 desired to be formed in the insulating layer may comprise, e.g., a bore or a through-hole having a selected depth and width.

The laser that generates the beam 32 may comprise, for example, an ultraviolet (UV) excimer laser, which patterns the insulating layer on the substrate 20 by a multiphoton absorption process. In one preferred embodiment, the UV excimer laser beam has a wavelength of about 193 nm (ArF) to about 351 nm (XeF), a maximum power of about 300 W, and a repetition rate (RR) of between from about 50 Hz to about 200 Hz. The UV excimer laser beam can form a pattern with a width and depth of about a 2 microns (1 μm=1×10⁻⁶ meters), and accordingly, UV excimer laser beams are often used to form patterns in polymers, thin inorganic layers and the like by ablation. As used herein, the term “the laser beam” means a beam generated or produced by a UV excimer laser.

Although not illustrated in the figures, those of skill in the art will appreciate that the apparatus may be equipped with a plurality of head sections 30, each equipped with a laser, which can reduce the amount of time involved in the manufacture of display substrates using the methods described herein.

With reference to FIG. 1, the transferring section 50 of the apparatus is capable of moving the head section 30 into selected positions with a selected speed, or “feed rate.” The feed rate is the velocity of horizontal movement of the head section 30 relative to a substrate work piece disposed below it, and is dependent on the performance level, i.e., ablation rate, of the apparatus. The head section 30, which is fixed beneath the transferring section 50, is moved by the transferring section to the selected position at which the desired patterns 21 are to be formed. By controlling the feed rate of the transferring section 50, the head section 30 can burn or etch the insulating layer formed on the display substrate in a controllable manner and thereby form the desired pattern 21 more easily.

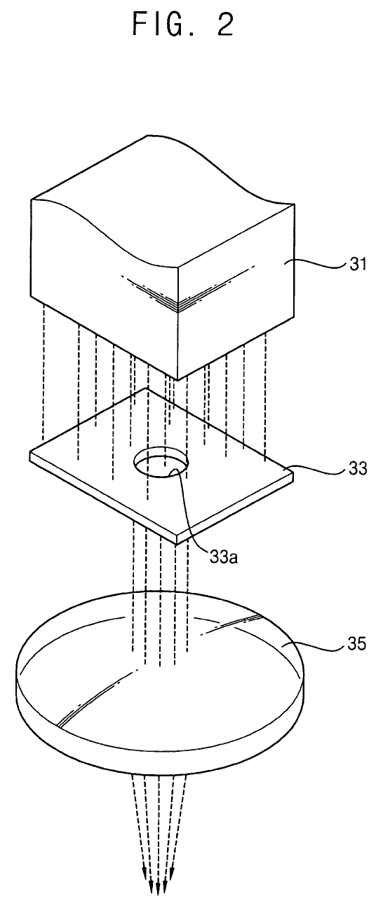

FIG. 2 is a partial upper side perspective view of the head section 30 of the apparatus of FIG. 1. Referring to both FIGS. 1 and 2, the head section 30 includes a light source part 31, a mask 33 and a projection lens 35. The light source part 31 generates the laser beam, concentrates it, and radiates the concentrated, high energy laser beam toward the mask 33. The mask 33 includes an opening pattern 33a having a selected size and shape. The laser beam, which radiates from the light source part 31, is modified by the mask 33 to incorporate a shape corresponding to the opening pattern 33a of the mask. The projection lens 35 serves to refract and focus the laser beam, modified with the shape of the mask's opening pattern 33a, onto the display substrate 20.

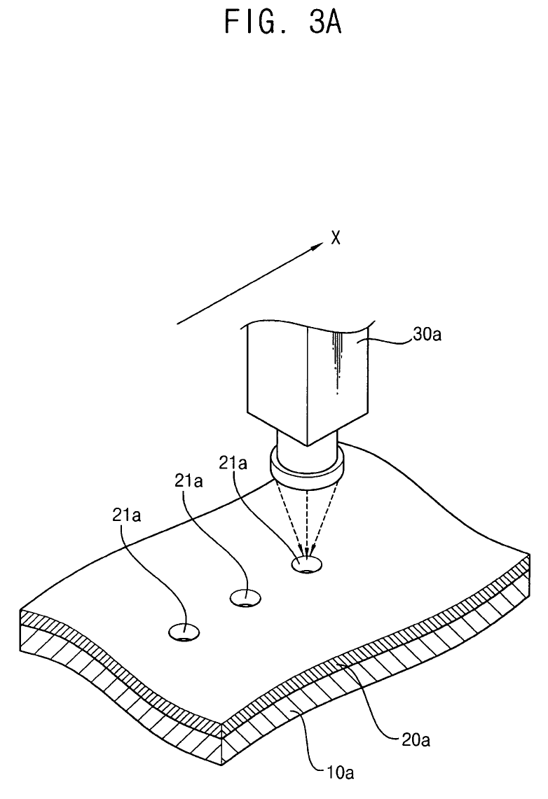

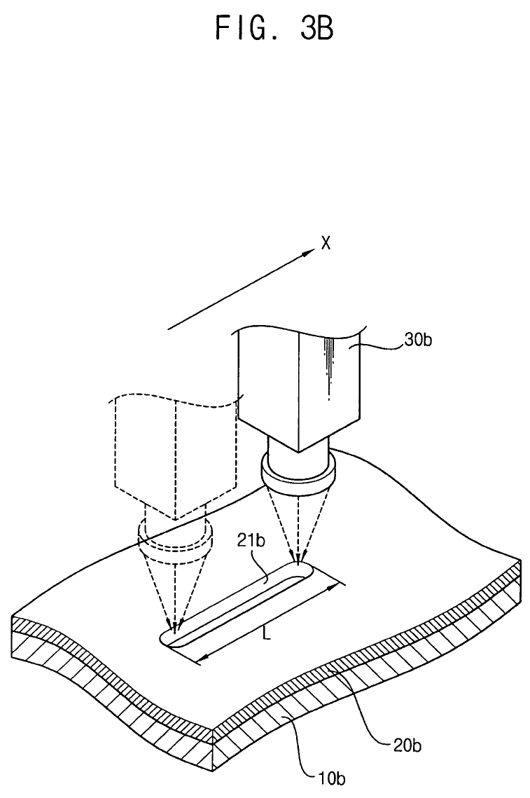

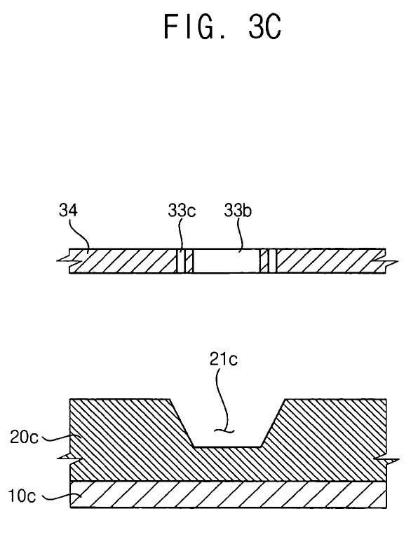

FIGS. 3A to 3C are partial upper side and cross-sectional views of the apparatus of FIG. 1 being used to effect three different patterning methods of the invention.

In more detail, FIG. 3A is a partial upper side view illustrating a first exemplary patterning method of the invention. The desired pattern is formed by the laser beam, which is radiated by a head section 30a, including a mask 33 having an opening pattern 33a therein. After a display substrate 20a which is to be patterned is disposed on the stage section 10a, the head section 30a is moved to a first position above the substrate. Then, the insulating layer of the display substrate 20a is sequentially patterned by the laser beam, which is radiated from the head section 30a onto the substrate 20a, to form a first hole-shaped pattern 21a in the layer. The head section is then moved in the direction of the arrow of FIG. 3A to a second position corresponding to a second hole-shaped pattern 21a to be formed, the pattern burned into the insulating layer, and so on, until all of the desired hole-shaped patterns 21a have been formed in the insulating layer of the substrate 20a. The method of forming a plurality of hole-shaped patterns 21a described above may be advantageously employed, for example, in making contact holes that electrically connect a switching element with a pixel electrode of the display substrate 20a.

FIG. 3B is a partial upper side view illustrating a second exemplary patterning method according to the present invention. As in the above embodiment, the desired pattern is formed by a laser beam, which is radiated from a head section 30b including a mask 33 having an opening pattern 33a therein. As illustrated in FIG. 3B, a display substrate 20b that is to be patterned is disposed on a stage section 10b, and the head section 30b is moves from a starting position to a first position. The head section 30b is then moved over the substrate in the direction X of the arrow shown while the laser beam is being radiated, and the total length ‘L’ of the distance moved by the head section 30b is programmably controlled by a controller (not illustrated). This programmed movement of the radiating head 30b forms a pattern 21b having an elongated groove shape in the display substrate 20b. The elongated groove-shaped pattern 21b formed by the above process may be used advantageously, for example, in making pad portions at the ends of wiring lines on a display substrate.

FIG. 3C is a partial cross-sectional view illustrating an exemplary third patterning method according to the present invention. In this embodiment, the predetermined pattern is also formed by a laser beam that is radiated from a head section (not illustrated in FIG. 3C) that includes a slit mask 34 of the type illustrated. After a display substrate 20c that is to be patterned is disposed on a supporting stage section 10c of the apparatus, the head section is moved to a first position. Then, the insulating layer of the display substrate 20c is patterned with the laser beam radiating from the light source part of the head, as above. However, as will be understood by reference to FIG. 3C, the laser beam comprises multiple portions that vary in intensity because the slit mask 34 includes openings that vary in area, such as the first opening pattern 33b and the second opening pattern 33C shown in the figure.

In particular, the area of the first opening pattern 33b is substantially larger than that of the second opening pattern 33C. Accordingly, the intensity of the laser beam passing through the first opening pattern 33b is substantially greater than that of the laser beam passing through the second opening pattern 33C. Thus, as the head section is translated longitudinally over the substrate 20C with the laser continuously radiating, the portion of the laser beam radiating through the first opening pattern 33b forms an elongated groove with a uniform depth and width on the display substrate 20c, and the portion of the beam radiating through the second opening pattern 33c forms a pattern having a uniform gradient, or taper, on either side of the groove, as illustrated in the cross-sectional view of FIG. 3C. From the foregoing, it may be seen that, by providing the head section with a slit mask 34, a longitudinal groove pattern 21c having a uniform depth and tapered sidewalls is formed on the display substrate. As discussed below, when the pattern 21c is formed on a first region of the display substrate, and is repeatedly formed on a second region adjacent and peripheral to the first region, a peak-shaped pattern can be formed advantageously on the display substrate 20c.

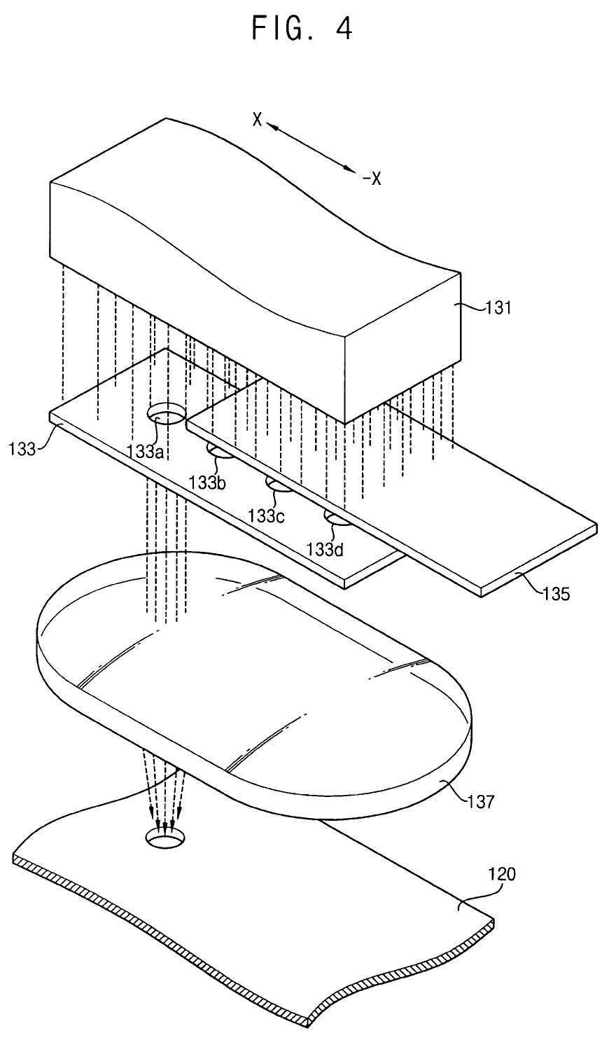

FIG. 4 is a partial upper side perspective view of the head section of an exemplary alternative embodiment of an apparatus for manufacturing an LCD substrate in accordance with the present invention. With reference to FIG. 4, the head section 130 includes a light source part 131, a mask 133, a diaphragm 135 and a projection lens 137. The head section 130 and the diaphragm are arranged to move independently of each other along an x-axis, indicated by the arrow in FIG. 4.

As in the first embodiment above, the light source part 131 generates a laser beam, concentrates it, and radiates the concentrated, high energy laser beam in the direction of a substrate 120 disposed below it. As above, the mask 133 includes a plurality of opening patterns 133a, 133b, 133c and 133d having respective selected shapes and sizes, and the laser beam radiating from the light source part 131 is accordingly modified by the mask to have a shape corresponding to the plurality of the opening patterns 133a, 133b, 133c and 133d of the mask. The diaphragm 135 is disposed between the mask 133 and the light source part 131, and is arranged to move along the x-axis shown. The diaphragm 135 functions to control the intensity of the laser beam radiating onto the mask 133 in the following manner.

In particular, moving the diaphragm 135 a first step, or distance, in the negative direction along the x-axis allows the laser beam to pass through only the first opening pattern 133a of the mask 133, while blocking its passage through the remaining opening patterns thereof. Then, by moving the diaphragm 135 a second step in the negative direction along the x-axis allows the laser beam to pass through both the first and second opening patterns 133a and 133b, while blocking its passage through the remaining openings. Moving the diaphragm 135 a third step in the negative x direction enables the laser beam to pass through the first, second and third opening patterns 133a, 133b and 133c. Finally, moving the diaphragm 135 a fourth step in the negative direction along the x-axis allows the laser beam to pass through all four opening patterns 133a, 133b, 133c and 133d of the mask 133. As will be understood, by moving the diaphragm 135 in the foregoing stepwise manner progressively increases the amount of time that the laser beam is allowed to radiate through the respective openings of the mask. Of course, in an alternative embodiment, the diaphragm 135 can be arranged to move in a positive direction along the x-axis, thereby progressively reducing the amount of time that the laser beam is allowed to radiate through the respective opening patterns of the mask 133.

The projection lens 137 is disposed between the mask 133 and the display substrate 120 that is to be patterned, and serves to refract and focus the laser beam that has been shaped by the openings of the mask onto a substrate that is to be patterned.

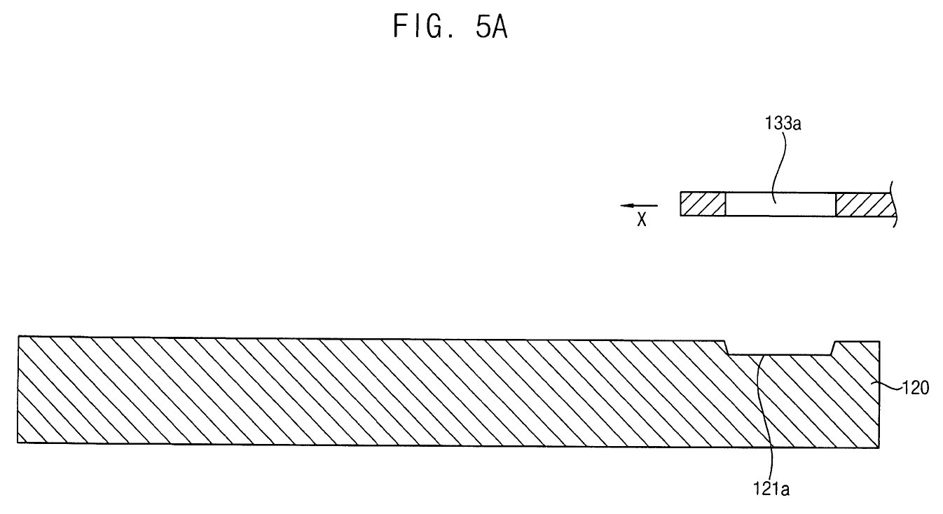

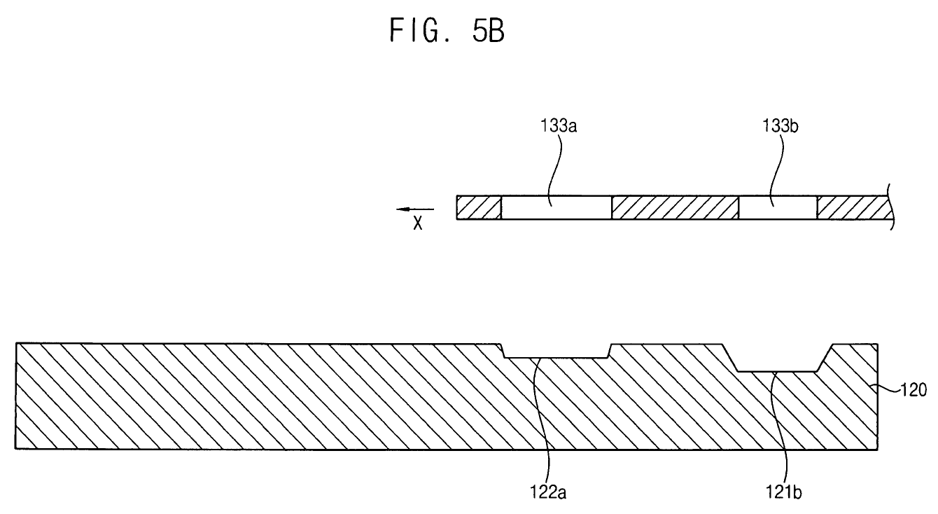

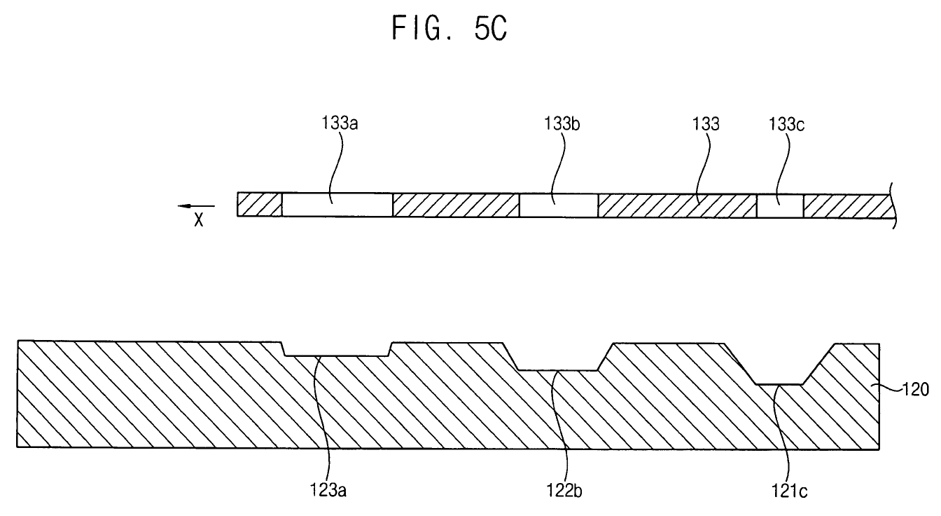

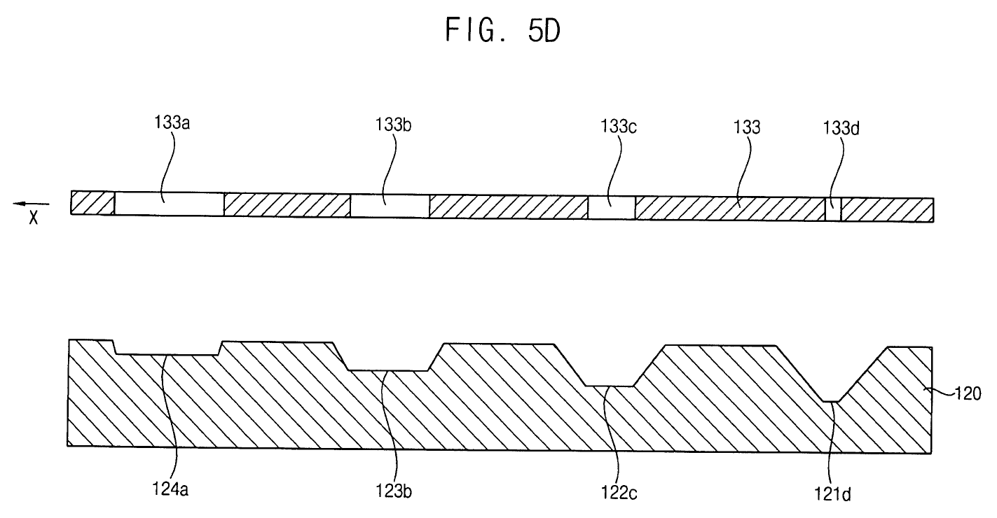

FIGS. 5A to 5D are sequential partial cross-sectional views of an insulating layer disposed on an LCD substrate being patterned with the alternative embodiment of apparatus of FIG. 4. With reference to FIGS. 4 and 5A, the head section 130, with the plurality of opening patterns 133a, 133b, 133c and 133d in the mask 133 thereof, is translated a first step in the positive direction along the x-axis shown in FIG. 4, and the diaphragm 135 is moved a first step in the negative direction along the x-axis shown in FIG. 5, so that the laser beam is allowed to pass through only the first opening pattern 133a of the mask. After the beam passes through the first opening pattern 133a, it is focused onto the substrate 120 by the projection lens 137 for a selected period of time so as to form a first pattern 121a at a first groove position on the substrate, as shown in FIG. 5A.

Referring to FIGS. 4 and 5B, the head section 130 is then moved a second step in the positive direction along the x-axis, and the diaphragm 135 is moved a second step in the negative direction along the x-axis, so that the laser beam passes through both the first and second opening patterns 133a and 133b of the mask 133. After it passes through the first and second opening patterns 133a and 133b of the mask 133, the laser beam is focused onto the substrate 120 by the projection lens 137 for a selected period of time so as to form the first and second patterns 121a and 121b at a second and the first groove positions, respectively.

As illustrated in FIG. 5B, as a result of the above relative movements of the head section 130 and the diaphragm 135, the second opening pattern 133b is located over the first groove position having the first pattern 121a previously formed therein, and the second pattern 121b corresponding to the second opening pattern 133b is then formed by the laser beam passing through the second opening pattern 133b. The first opening pattern 133a is now disposed over the second groove position in which a pattern has yet to be formed, and the first pattern 121a corresponding to the first opening pattern 133a is then formed by the laser beam passing through the first opening pattern 133a.

Referring to FIGS. 4 and 5C, the head section 130 with its mask opening patterns 133a, 133b, 133c and 133d is then moved a third step in the positive direction along the x-axis, and the diaphragm 135 is moved a third step in the negative direction along the x-axis, so that the laser beam is allowed to pass through the first, second and third opening patterns 133a, 133b and 133c of the mask 133. As illustrated in FIG. 5C, after it passes through the first, second and third opening patterns 133a, 133b and 133c of the mask 133, the laser beam is focused onto the substrate 120 by the projection lens 137 for a selected period of time so as to form the patterns 121a, 121b and 121c at a third, the second and the first groove positions of the substrate, respectively.

As shown in FIG. 5C, as a result of the foregoing respective, relative movements of the head section 130 and the diaphragm 135, the third opening pattern 133c of the mask 133 is located over the first groove position having the first and second patterns 121a and 121b previously formed therein, and the third pattern 121c corresponding to the third opening pattern 133c is thus formed at the first groove position by the laser beam passing through the third opening pattern 133c. The second opening pattern 133b of the mask 133 is disposed over the second groove position having the first pattern 121a previously formed therein, and the second pattern 121b corresponding to the second opening pattern 133b is then formed at the second groove position by the laser beam passing through the second opening pattern 133b. The first opening pattern 133a of the mask 133 is located over the third groove position on which a pattern has yet to be formed, and the first pattern 121a corresponding to the first opening pattern 133a is then formed at the third groove position by the laser beam passing through the first opening pattern 133a of the mask 133.

Referring to FIGS. 4 and 5D, the head section 130 and mask opening patterns 133a, 133b, 133c and 133d is then moved a fourth step in the positive direction along the x-axis, and the diaphragm 135 is moved a fourth step in the negative direction along the x-axis, so that the laser beam passes through all four opening patterns 133a, 133b, 133c and 133d of the mask 133. After passing through all of the mask openings, the laser beam is focused onto the substrate 120 by the projection lens 137 for a selected period of time to form the patterns 121a, 121b, 121c and 121d at a fourth, the third, the second and the first groove positions, respectively.

As shown in FIG. 5D, as a result of the respective, relative movements of the head section 130 and the diaphragm 135, the fourth opening pattern 133d of the mask 133 is located over the first groove position having the first pattern 121a, the second pattern 121b and the third pattern 121c previously formed therein, and the fourth pattern 121d corresponding to the fourth opening pattern 133d is then formed by the laser beam passing through the fourth opening pattern 133d of the mask 133. The third opening pattern 133c is disposed over the second groove position having the first pattern 121a and the second pattern 121b previously formed therein, and the third pattern 121c corresponding to the third opening pattern 133c is then formed by the laser beam passing through the third opening pattern 133c. The second opening pattern 133b is located over the third groove position having the first pattern 121a previously formed therein, and the second pattern 121b corresponding to the second opening pattern 133b is then formed by the laser beam passing through the second opening pattern 133b. The first opening pattern 133a of the mask 133 is located over the fourth groove position on which a pattern has yet to be formed, and the first pattern 121a corresponding to the first opening pattern 133a is then formed by the laser beam passing through the first opening pattern 133a.

After form-ing four patterns 121a, 121b, 121c and 121d on the substrate, the head section 130 is moved step-by-step in the positive direction along the x-axis with the diaphragm 135 opened, and forms a plurality of patterns on the display substrate 120 using the manufacturing process previously described. Since the laser beam has a Gaussian profile, all of the groove shape patterns are formed with respective sidewalls having substantially the same slope. The manufacturing process described above, which radiates the laser beam in a step-by-step fashion to form a single pattern, is sometimes referred to as a synchronized image scanning (SIS) process.

As discussed above, the insulating layer of the display substrate 120 may be patterned in a stepwise process by using a mask having different opening patterns, and the SIS process may also be used to manufacture the contact holes of the switching elements and the pad portions. Additionally, a wide variety of other shapes of patterns can be formed in accordance with the shape, size and number of opening patterns of the mask 133.

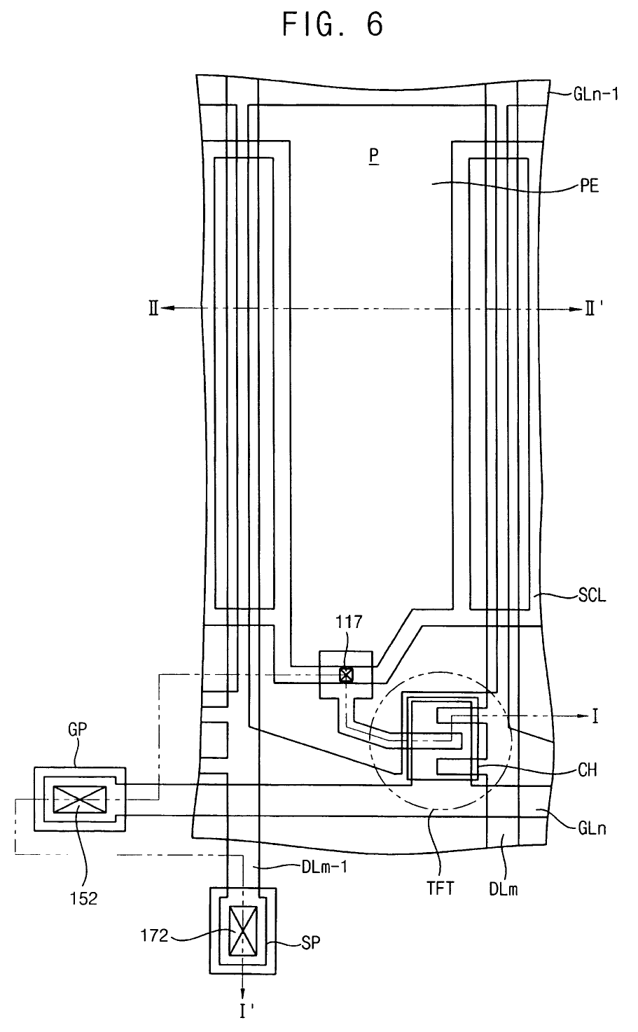

FIG. 6 is a partial plan view of an LCD substrate 120 manufactured by the apparatus illustrated in FIG. 1, and illustrates a single representative pixel portion thereof. With reference to FIG. 6, the display substrate 120 includes a plurality of gate lines GLn-1 to GLn, a plurality of source lines DLm-1 to DLm and a plurality of pixel portions P defined by the gate lines GLn-1 to GLn and the source lines DLm-1 to DLm. The gate lines GLn-1 to GLn are arrayed in a first direction and extend in a second direction. The source lines DLm-1 to DLm are arrayed in the second direction and extend in the first direction, i.e., the gate and source lines are arranged generally orthogonal to each other.

Gate pad portions GP are formed at an end portion of the gate lines GLn-1 to GLn and source pad portions SP are formed at an end portion of the source lines DLm-1 to DLm. A switching element comprising a thin film transistor (TFT), a storage common line SCL, and a pixel electrode PE are also formed at the pixel portions P. The switching element TFT is electrically connected to an nth gate line GLn, an mth data line DLm and the pixel electrode PE.

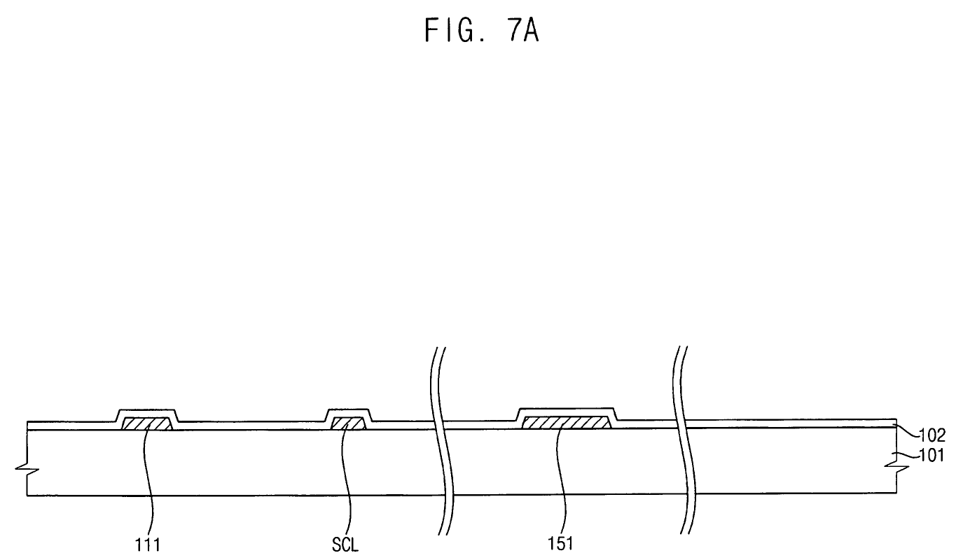

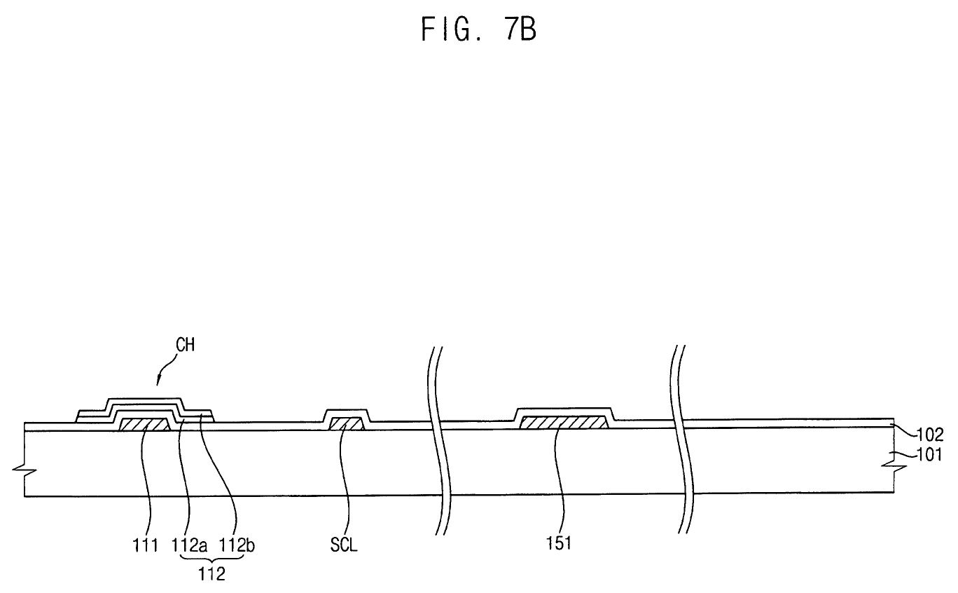

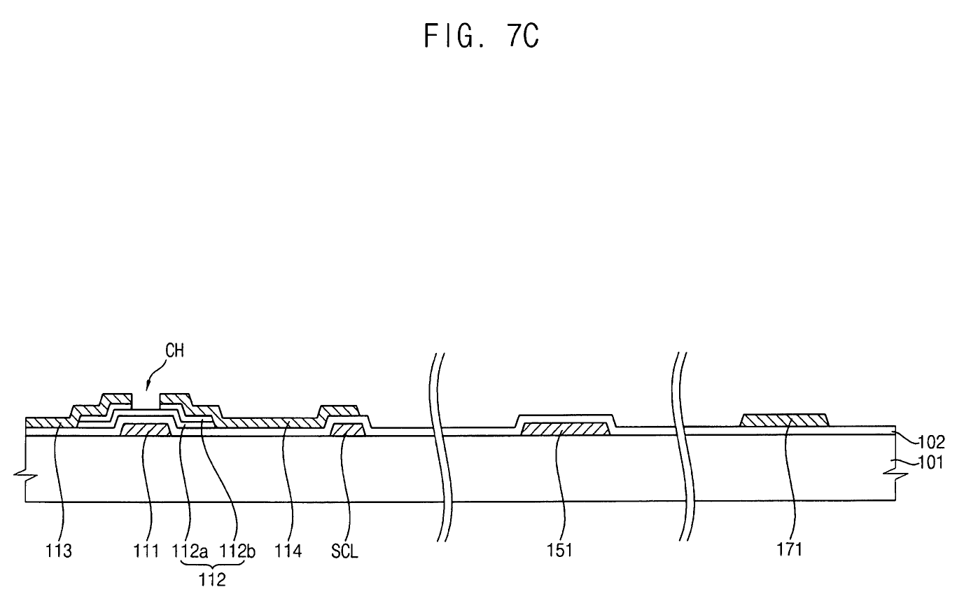

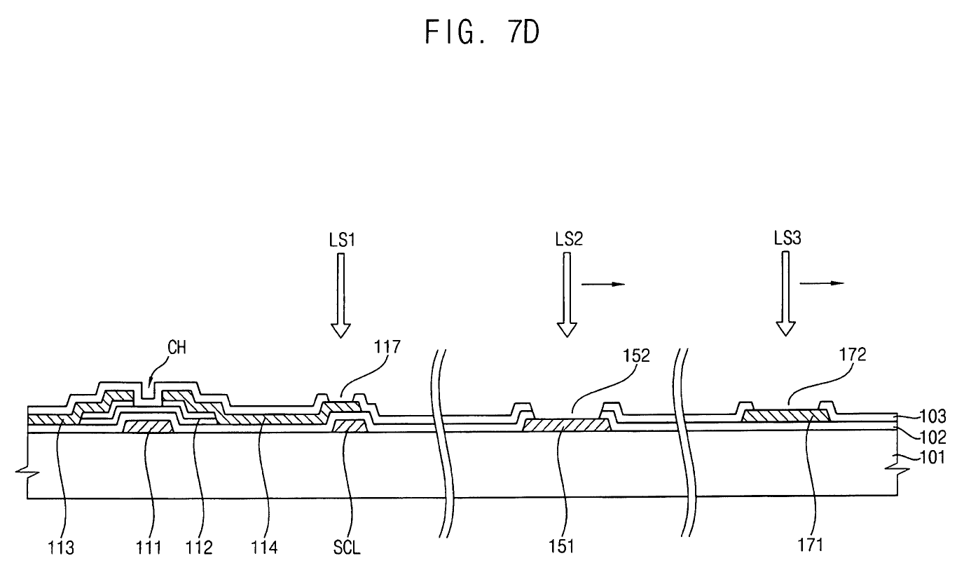

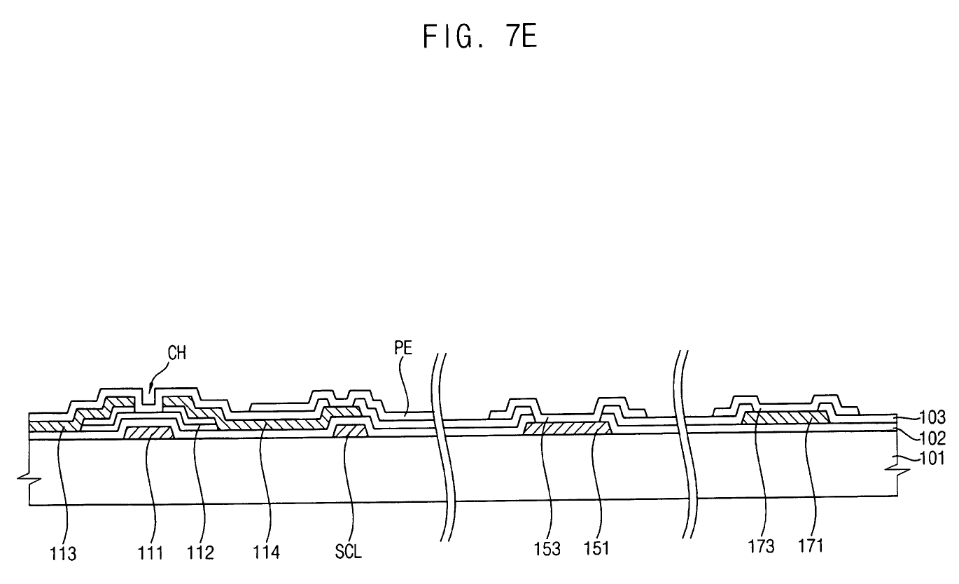

FIGS. 7A to 7E are sequential cross-sectional views of the substrate 120 of FIG. 6 corresponding to cross-sectional views taken along the section line I-I′ therein and illustrating the successive stages of a first exemplary embodiment of a method for manufacturing the display substrate in accordance with the present invention.

Referring to FIGS. 6 and 7A, a metallic gate layer is formed on a base substrate 101. The metallic gate layer is patterned by using a first mask to form a plurality of metallic gate patterns, including the plurality of gate lines GLn-1 to GLn, the gate electrode 111 of the switching element TFT, and the storage common line SCL, all concurrently with each other. A gate insulating layer 102 is then formed over the base substrate 101 and the metallic gate patterns formed thereon.

Referring to FIGS. 6 and 7B, a channel layer 112 is formed on the gate insulating layer 102. The channel layer 112 includes an active layer 112a and an ohmic contact layer 112b. The active layer 112a may be disposed between the gate insulating layer 102 and the ohmic contact layer 112b. The active layer 112a includes amorphous silicon, and the ohmic contact layer 112b includes n+amorphous silicon with a dopant doped through an in-situ process. The channel layer 112 is then patterned to form a channel pattern CH on the gate electrode 111 of the switching element TFT using a second mask.

Referring to FIGS. 6 and 7C, a metallic source layer is formed on the base substrate 101 having the previously formed channel pattern CH thereon. The metallic source layer is patterned by using a third mask to concurrently form a plurality of metallic source patterns, including the source lines DLm-1 to DLm, a source electrode 113 of the switching element TFT and a drain electrode 114 of the switching element TFT. A portion of the channel pattern CH, which is disposed between the source electrode 113 and the drain electrode 114, is etched by using the source and drain electrodes 113 and 114 as a mask to form the ohmic contact layer 112b.

With reference to FIGS. 1 to 7D, an insulating layer 103 (referred to herein as a “passivation layer”) is formed on the base substrate 101 having the plurality of metallic source patterns previously formed thereon. The passivation layer 103 can comprise an inorganic material or an organic material and has a thickness of no more than about 4000 angstrom. The passivation layer 103 and the gate insulating layer 102 are then etched by a laser beam radiated from the apparatus illustrated in FIG. 1 or 4 in the manner described above.

In particular, as shown in FIGS. 3A and 7D, the laser beam LS1 passing through the mask 33 having a circular opening pattern therein, etches the passivation layer 103 on the drain electrode 114 of the switching element TFT, thereby forming a first contact hole 117 through the passivation layer.

Then, as illustrated in FIGS. 3B and 7D, the head section 30 of the apparatus is translated for a selected distance over the substrate with the laser beam LS2 continuously radiating so as to etch through both the passivation layer 103 and the gate insulating layer 102 on the gate pad portion GP, thereby forming a second contact hole 152 having a length equal to the selected distance.

Using substantially the same method as described above, the laser beam LS3 then etches the passivation layer 103 on the source pad portion SP to form a third contact hole 172 having a selected length.

Alternatively, as illustrated in FIG. 3A, the gate insulating layer 102 and the passivation layer 103 may be patterned by a head section 30 having an opening pattern size and configuration corresponding to the size and configuration of the second and third contact holes 152 and 172, respectively.

Alternatively, the first, second and third contact holes 117, 152 and 172 may be formed by the apparatus illustrated in FIG. 4. For example, a mask 133 having substantially the same shape of the opening pattern, as illustrated in FIGS. 5A to 5D, may be used for forming the contact holes. In other words, the laser beam passing through a mask having substantially the same shape of the opening pattern serves to etch the passivation layer 103 in a step-by-step process to form the contact holes, as described above. Additionally, the laser beam passing through a selected mask opening pattern and controlled by the diaphragm as described above may be used to form the selected shape of the contact holes.

Referring to FIGS. 6 and 7E, the pixel electrode PE layer is formed on the passivation layer 103 where the first, second and third contact holes 117, 152 and 172 are patterned thereon. The pixel electrode PE includes an optically transparent and electrically conductive material, such as indium tin oxide (ITO), indium zinc oxide (IZO), indium tin zinc oxide (ITZO), or the like. The pixel electrode is formed such that it is respectively electrically connected to the drain electrode 114 through the first contact hole 117, to a metallic gate pattern 151 in the gate pad portion GP through the second contact hole 152, and to a metallic data pattern 171 in the source pad portion SP through the third contact hole 172. The pixel electrode layer is then patterned by using a fourth mask to form the pixel electrode PE in the pixel portion P, a first pad electrode 153 in the gate pad portion GP, and a second pad electrode 173 in the source pad portion SP, all patterned concurrently with each other.

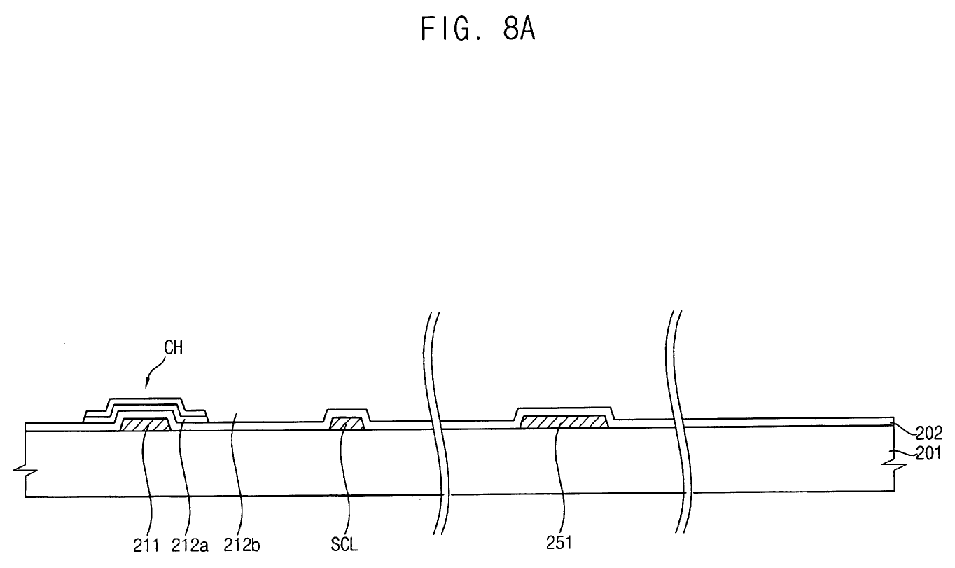

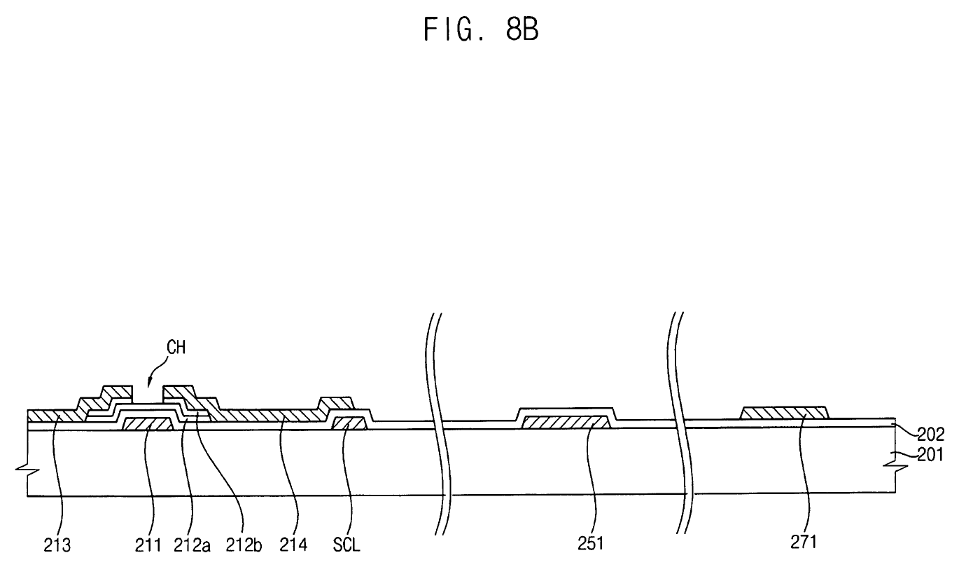

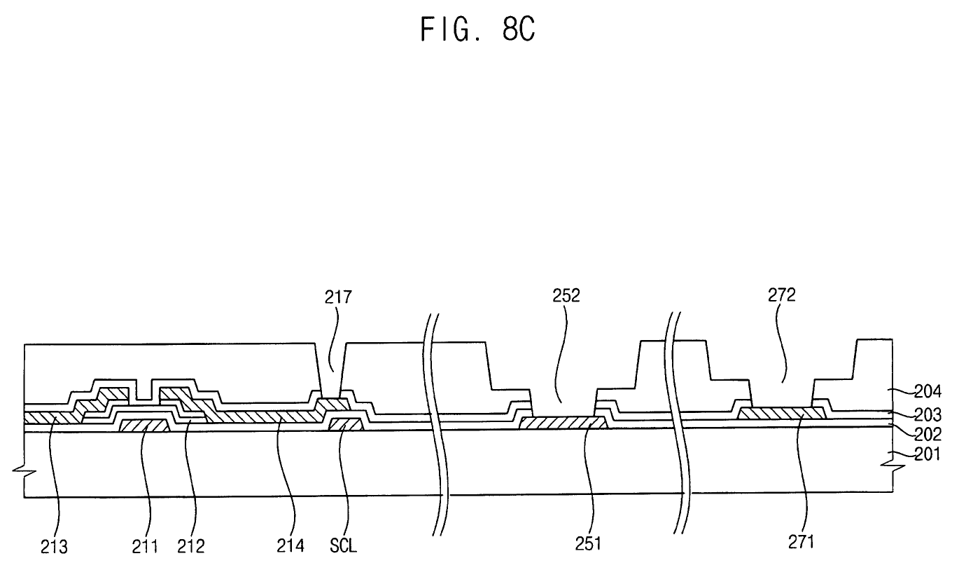

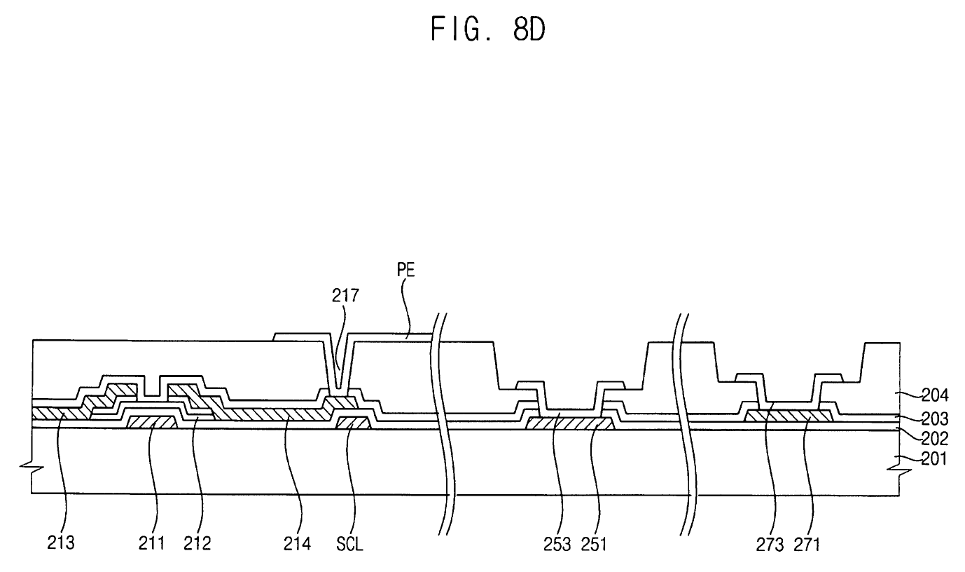

FIGS. 8A to 8D are sequential cross-sectional views of the display substrate 120 of FIG. 6 corresponding to successive cross-sectional views taken along the section line I-I′ therein and illustrating the successive stages of a second exemplary embodiment of a method for manufacturing the substrate in accordance with the present invention.

Referring to FIGS. 6 and 8A, a metallic gate layer is formed on the base substrate 201. The metallic gate layer is patterned using a first mask to concurrently form a plurality of metallic gate patterns comprising a plurality of gate lines GLn-1 to GLn, a gate electrode on the switching element TFT and the storage common line SCL. A gate insulating layer 202 is then formed on the base substrate 201 and the plurality of metallic gate patterns formed thereon. The active layer 212a is formed on the gate insulating layer 202, and the ohmic contact layer, including n+ amorphous silicon having dopant doped through an in-situ process, is formed on the active layer 212a to form a channel layer 212. The channel layer 212 is then patterned using a second mask to form a channel pattern CH covering a portion of the gate electrode 211.

Referring to FIGS. 6 and 8B, a metallic source layer is then formed on the base substrate 201 and the channel pattern CH formed thereon. The source metallic layer is then patterned by a third mask to concurrently form the metallic source patterns, including source lines DLm-1 to DLm, a source electrode 213 of the switching element TFT, and a drain electrode 214 of the switching element TFT. A portion of the channel pattern CH disposed between the source electrode 113 and the drain electrode 114 is then etched using the source and drain electrodes 113 and 114 as a mask to form an ohmic contact layer 112b.

Referring to FIGS. 1, 6 and 8C, a passivation layer 203 and an organic insulating layer 204 are sequentially formed on the base substrate 201 having the plurality of metallic source patterns formed thereon. The passivation layer 203 can comprise an inorganic or an inorganic insulating material, and has a thickness of no more than about 4000 angstrom, whereas, the organic insulating layer 204 has a thickness of about 2 μm to about 4 μm. The passivation layer 203 and the organic insulating layer 204 are then etched by the laser beam radiated from the apparatus illustrated in FIGS. 1 and 4.

In particular, as illustrated in FIG. 3A, a laser beam passing through a mask 33 having a circular opening pattern therein etches the passivation layer 203 on the drain electrode 214 of the switching element TFT and the organic insulating layer 204 on the passivation layer 203 to form a first contact hole 217. The first contact hole 217 may be also formed by the apparatus of FIG. 4. For example, as described above in connection with the manufacturing process of FIGS. 5A to 5D, a mask 133 having an opening pattern with substantially the same shape as the desired contact hole may be used to form the contact hole. Alternatively, by adjusting the diaphragm 135 so that the laser beam passes through a selected opening pattern having the desired shape, the desired contact hole shape may be formed in both the passivation layer 203 and the organic insulating layer 204. Then, by using the step-by-step manufacturing processes described above and illustrated in FIGS. 3C and 5A to 5D, the laser beam passing through the appropriate opening pattern etches the gate insulating layer 202 formed on the gate pad portion GP, the passivation layer 203 and the organic insulating layer 201 to form a second contact hole 252. Then, using substantially the same process by which the second contact hole 252 were formed, the laser beam etches the passivation layer 203 formed on the source pad portion SP and the organic insulating layer 204 to form a third contact hole 272.

Referring to FIGS. 6 and 8D, the pixel electrode layer is formed on the organic substrate 204 with the first, the second and the third contact holes 217, 252 and 272 previously formed thereon. As above, the pixel electrode layer includes an optically transparent and electrically conductive material, such as indium tin oxide (ITO), indium zinc oxide (IZO), indium tin zinc oxide (ITZO), or the like. The pixel electrode is respectively electrically connected to the drain electrode 214 through the first contact hole 217, a metallic gate pattern 251 in the gate pad portion GP through the second contact hole 252, and a metallic data pattern 271 in the source pad portion SP through the third contact hole 272. The pixel electrode layer is then patterned using a fourth mask to form concurrently the pixel electrode PE on the pixel portion P, a first pad electrode 253 on the gate pad portion GP, and a second pad electrode 273 on the source pad portion SP.

As may be noted from the above, the second contact hole 252 of the gate pad portion GP and the third contact hole 272 in the source pad portion SP in FIG. 8C are formed with “stepped portions.” In other words, an upper portion of each of the second and third contact holes 252 and 272 has a greater diameter than a diameter of a lower portion of each of the second and third contact holes 252 and 272, respectively. As a result, electrical contact can easily be made between the second and third contact holes 252 and 272 and the output pads of an external device. Typically, the gate pad portion GP and the source pad portion SP are electrically connected to an output terminal of external equipment through an anisotropic conductive film (ACF). The stepped characteristic of the contact holes described above and the benefits thereof are disclosed in Korean Laid-Open Patent Publication No. 2002-63424, entitled “Liquid crystal display device and method for manufacturing the same.”

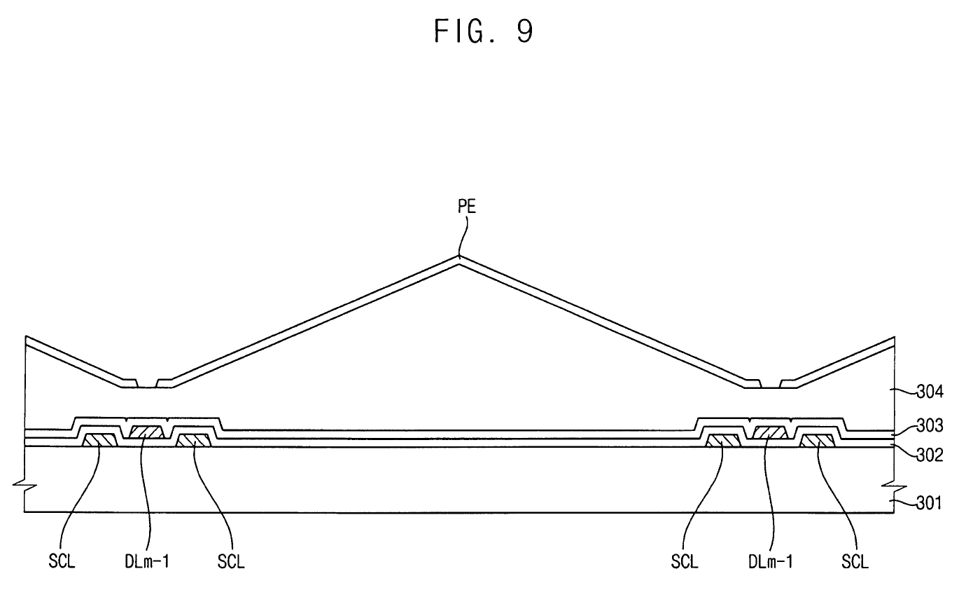

FIG. 9 is a partial cross-sectional view of the display substrate 120 taken along the lines II-II′ in FIG. 6, and illustrates another aspect of the methods for manufacturing the substrate in accordance with the present invention. Referring to FIGS. 6 and 9, the metallic gate layer is deposited on the base substrate 301 and patterned to concurrently form the plurality of metallic gate patterns, including the plurality of gate lines GLn-1 to GLn, the gate electrode on the switching element TFT and the storage common line SCL, as above. A gate insulating layer 302 is then formed on the base substrate 301 and the plurality of metallic gate patterns formed thereon. The channel layer is then deposited and patterned on the gate insulating layer 302 to form the channel layer 112 layered on the gate electrode of the switching element TFT.

The metallic source layer is then deposited and patterned on the base substrate 301 with the channel layer 112 formed thereon to concurrently form the plurality of metallic source patterns, including the plurality of source lines DLm-1 to DLm, the source electrode of the switching element TFT and the drain electrode of the switching element TFT.

A protective insulating layer or passivation layer3O3 and an organic insulating layer 304 are then sequentially formed on the base substrate 301 and the plurality of metallic source patterns formed thereon. When an organic insulating layer 304 is formed on the base substrate 301, the use of a passivation layer 303 is optional. The organic insulating layer 304, the passivation layer 303 and the gate insulating layer 302 are then selectively etched using the apparatus illustrated in FIGS. 1 and 4 to form a desired pattern therein. In particular, as illustrated in FIG. 9, the organic insulating layer 304 formed on the pixel portion P area is patterned to have a peaked shape. When the apparatus of FIG. 1 is used, a slit mask 34 of the type illustrated in FIG. 3C may be used advantageously to pattern the organic insulating layer 304 to have the peaked shape illustrated in FIG. 9.

Additionally, when an apparatus of the type described above and illustrated in FIGS. 5A to 5D is used, the organic insulating layer 304 may be patterned into the peaked shape using the SIS process described above.

In either case, the organic insulating layer 304 and the passivation layer 303 are respectively etched with the laser beam radiating from the light source part to form the first contact hole 117, thereby exposing a small portion of the drain electrode of the switching element TFT, the second contact hole 152, thereby exposing a small portion of the gate metallic layer of the gate pad portion GP, and the third contact hole 172, thereby exposing a small portion of the source metallic layer of the source pad portion SP, respectively.

Then, the pixel electrode layer is deposited and patterned on the organic insulating layer 304 to form the pixel electrode PE, as above. The pixel electrode PE is then electrically connected with the drain electrode of the switching element TFT through the first contact hole. In addition, the first and the second pad electrodes are formed. The first pad electrode is connected with the metallic gate layer through the first contact hole 117, and the second pad electrode is connected with the metallic source layer through the second contact hole 152.

As will be appreciated, by patterning the organic insulating layer of the pixel portions P to incorporate the peaked shapes as described above and illustrated in FIG. 9, the alignment angle of the liquid crystal molecules disposed between the substrates of the LCD can be more readily controlled. Accordingly, the viewing angle, i.e., the range of angles at which an image on the LCD can be seen by a viewer thereof, can be substantially increased.

In accordance with the methods and apparatus of the present invention, by using a laser beam controllably radiated from a light source part of an apparatus to selectively pattern the insulating layer on an LCD substrate, the complicated apparatus and manufacturing methods of conventional photolithography techniques used in the past are substantially simplified. Furthermore, the reliability of the LCD manufacturing process is substantially enhanced by the precision with which the shapes and positions of the patterns can be formed by the apparatus and methods of the present invention.

By now, those of skill in this art will appreciate that many modifications, substitutions and variations can be made in and to the methods and apparatus of the present invention and their advantageous use in manufacturing LCD substrates without departing from its spirit and scope. In light of this, the scope of the present invention should not be limited to that of the particular embodiments illustrated and described herein, as they are only exemplary in nature, but instead, should be fully commensurate with that of the claims appended hereafter and their functional equivalents.

What is claimed is:

1. A method for manufacturing a display substrate having a plurality of pixel portions, each comprising a switching element electrically connected to a gate line and a source line, and a pixel electrode electrically connected to the switching element, the method comprising:
forming a gate electrode of the switching element on a base substrate;
forming a gate insulating layer on the base substrate having the gate electrode formed thereon;
forming a source electrode and a drain electrode of the switching element on the gate insulating layer;
forming a protective insulating layer on the base substrate having the source electrode and the drain electrode formed thereon;
radiating a laser beam onto the protective insulating layer so as to form a first contact hole therein exposing a portion of the drain electrode; and,
forming the pixel electrode such that it is electrically connected to the drain electrode through the first contact hole.

2. The method of claim 1, wherein the laser beam is generated by an ultraviolet (UV) excimer laser.

3. The method of claim 1, wherein the gate line is formed concurrently with the forming of the gate electrode.

4. The method of claim 1, wherein forming the first contact hole further comprises radiating the laser beam onto the protective insulating layer so as to form a second contact hole exposing a portion of the gate line.

5. The method of claim 4, wherein a first pad electrode that is electrically connected with a portion of the gate line through the second contact hole is formed concurrently with the forming of the pixel electrode.

6. The method of claim 1, wherein the source line is formed concurrently with the forming of the source electrode and the drain electrode.

7. The method of claim 6, wherein forming the first contact hole further comprises radiating the laser beam onto the protective insulating layer so as to form a third contact hole exposing a portion of the source line.

8. The method of claim 7, wherein a second pad electrode is formed concurrently with the forming the pixel electrode, and wherein the second pad electrode is formed such that it is electrically connected with a portion of the source line through the third contact hole.

9. A method for manufacturing a display substrate having a plurality of pixel portions, each comprising a switching element electrically connected to a gate line and a source line, and a pixel electrode electrically connected to the switching element, the method comprising:
forming a gate electrode of the switching element on a base substrate;
forming a gate insulating layer on the base substrate having the gate electrode formed thereon;
forming a source electrode and a drain electrode of the switching element on the gate insulating layer;
forming a organic insulating layer on the base substrate having the source electrode and the drain electrode formed thereon;
radiating a laser beam onto the organic insulating layer so as to form a first contact hole exposing a portion of the drain electrode; and,
forming the pixel electrode such that it is electrically connected to the drain electrode through the first contact hole.

10. The method of claim 9, wherein the laser beam is produced by a UV excimer laser.

11. The method of claim 9, further comprising forming a protective insulating layer disposed between the organic insulating layer and the source and the drain electrodes.

12. The method of claim 9, wherein the gate line is formed concurrently with the forming of the gate electrode.

13. The method of claim 9, wherein forming the first contact hole further comprises radiating the laser beam onto the organic insulating layer so as to form a second contact hole exposing a portion of the gate line.

14. The method of claim 9, wherein forming the first contact hole further comprises patterning the organic insulating layer to include a peaked shape using the laser beam, and wherein the pixel electrode is formed on the organic insulating layer.

15. The method of claim 12, wherein a first pad electrode that is electrically connected with a portion of the gate line through the second contact hole is formed concurrently with the forming of the pixel electrode.

16. The method of claim 9, wherein the source line is formed concurrently with the forming of the source electrode and the drain electrode.

17. The method of claim 16, wherein forming the first contact hole further comprises radiating the laser beam onto the organic insulating layer so as to form a third contact hole exposing a portion of the source line.

18. The method of claim 17, wherein a second pad electrode is formed concurrently with the forming of the pixel electrode, and wherein the second pad electrode is formed such that it is electrically connected with a portion of the source line through the third contact hole.

19. An apparatus for manufacturing a display substrate, comprising:
a head section that radiates a laser beam;
a transferring section that moves the head section to selected positions, the head section being coupled with the transferring section; and,
a stage section on which the display substrate is disposed,
wherein an insulating layer of the display substrate disposed on the stage section is patterned by the laser beam.

20. The apparatus of claim 19, wherein the laser beam is generated by a UV excimer laser.

21. The apparatus of claim 19, wherein the head section comprises:
a light source part that generates the laser beam;
a mask, including a opening pattern that forms the laser beam into a predetermined shape; and,
a projection lens that focuses the laser beam onto the display substrate after the laser beam passes through the opening pattern of the mask.

22. The apparatus of claim 19, further comprising a movable diaphragm that controls the intensity of the laser beam.

23. The apparatus of claim 22, wherein the diaphragm is disposed between the mask and the light source part.
